(19) United States
(12) Patent Application Publication
(10) Pub. No.: US 2014/0184241 A1
(43) Pub. Date: Jul. 3, 2014

(54) ELECTROMAGNETIC COMPATIBILITY TESTING SYSTEM

(71) Applicant: HON HAI PRECISION INDUSTRY CO., LTD., New Taipei (TW)

(72) Inventor: TEN-CHEN HO, New Taipei (TW)

(73) Assignee: HON HAI PRECISION INDUSTRY CO., LTD., New Taipei (TW)

(21) Appl. No.: 14/065,606

(22) Filed: Oct. 29, 2013

(30) Foreign Application Priority Data
Dec. 28, 2012 (CN) 2012105834439

(51) Int. Cl. G01R 27/32

(52) U.S. Cl. CPC G01R 27/32
USPC 324/602

(57) ABSTRACT

An electromagnetic compatibility testing system includes an anechoic chamber. The anechoic chamber includes a testing table, an antenna, an amplifier, and a receiver. A test sample is placed on the testing table. The antenna receives electromagnetic signals emitted by the test sample and transmits the electromagnetic signals to the amplifier via a coaxial cable. The receiver is connected to the amplifier via the coaxial cable analyzing the electromagnetic signals amplified by the amplifier.

### TECHNICAL FIELD

The disclosure generally relates to testing systems, and particularly to an electromagnetic compatibility testing system.

### DESCRIPTION OF RELATED ART

Electromagnetic compatibility testing systems usually include an anechoic chamber, an antenna set inside the anechoic chamber, and an amplifier and a receiver set outside the anechoic chamber. The antenna receives electromagnetic signals emitted from a test sample and transmits the electromagnetic signals to the amplifier and the receiver via a coaxial cable. However, because the amplifier and the receiver are set outside the anechoic chamber, the coaxial cable connecting the antenna to the amplifier is often long, and the electromagnetic signals may be significantly attenuated, which adversely affects accuracy of test results of the electromagnetic signals.

Therefore, it is desirable to provide a means to overcome the above-mentioned problems.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an isometric view of an electromagnetic compatibility testing system in accordance with an exemplary embodiment of the present disclosure, wherein the electromagnetic compatibility testing system includes an anechoic chamber having a number of absorbing projections formed therein.

FIG. 2 is a partial enlarged view of the absorbing projections of FIG. 1 showing an interior structure of the absorbing projections.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.”

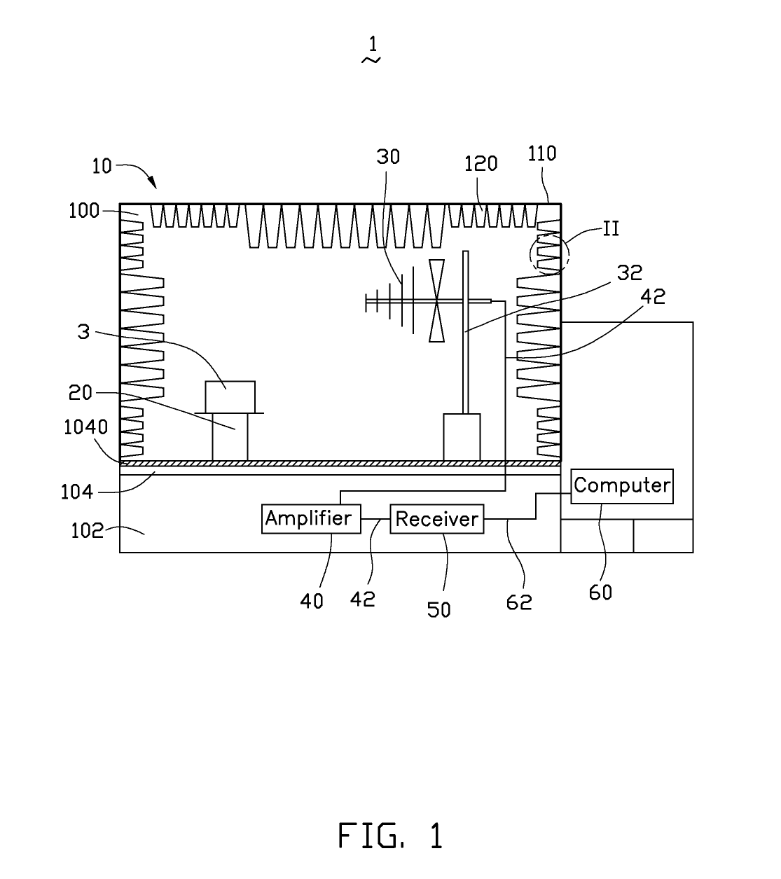

FIG. 1 illustrates an electromagnetic compatibility testing system 1 in accordance with an exemplary embodiment. The electromagnetic compatibility testing system 1 includes an anechoic chamber 10, a testing table 20, an antenna 30, an amplifier 40, a receiver 50, and a computer 60. The testing table 20, the antenna 30, the amplifier 40, and the receiver 50 are all located in the anechoic chamber 10. A test sample 3 is placed on the testing table 20. The antenna 30 receives an electromagnetic signal emitted from the test sample 3. The antenna 30 is connected to the amplifier 40 via a coaxial cable 42 to transmit the electronmagnetic signals received from the antenna 30 to the amplifier 40. The amplifier 40 is connected to the receiver 50 via the coaxial cable 42. The electromagnetic signal amplified by the amplifier 40 is transmitted to the receiver 50 through the coaxial cable 42.

The anechoic chamber 10 includes a testing part 100, a shielding part 102, and a shielding board 104 set between the testing part 100 and the shielding part 102. The shielding board 104 includes a grounded shielding sheet 1040 set on a surface of the shielding board 104 facing the testing part 100. The shielding sheet 1040 is made of a conductive material, such as copper, iron, or aluminum. The testing table 20 and the antenna 30 are set inside the anechoic chamber 10. The amplifier 40 and the receiver 50 are located inside the shielding part 102 to reduce interaction between the test sample 3 and the amplifier 40 or between the test sample 3 and the receiver 50. In this embodiment, the testing part 100 and the shielding part 102 are oriented along a vertical direction. The testing part 100 is located above the shielding part 102 and may occupy a majority of space of the anechoic chamber 10.

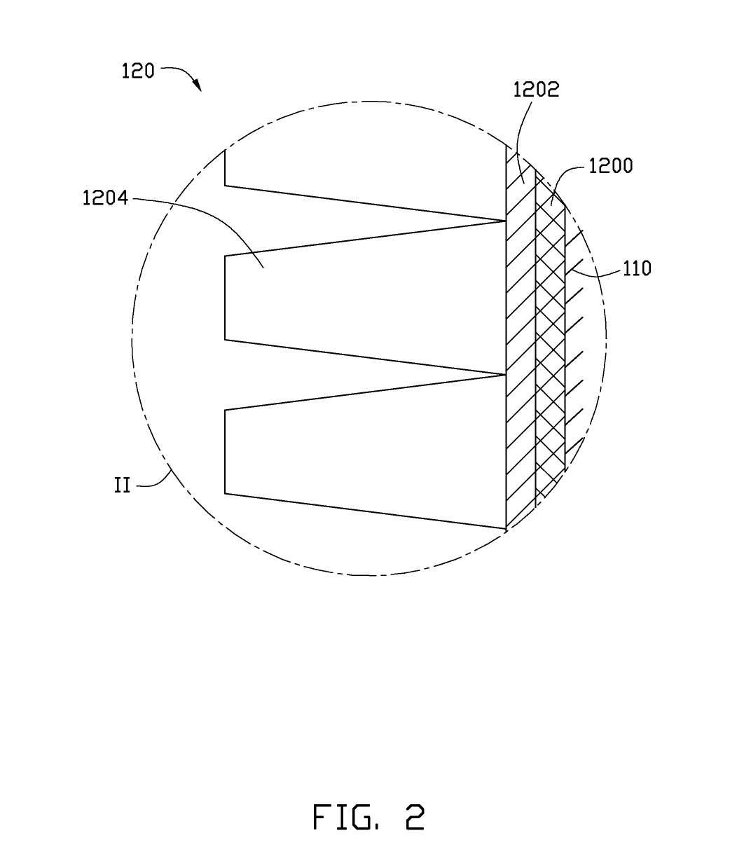

In FIG. 2, the testing part 100 includes sidewalls 110 and an absorber 120 formed on the sidewalls 110. The absorber 120 absorbs the electromagnetic signals emitted to the sidewalls 110 to prevent the electronmagnetic signals from reflecting off the sidewalls 110 and affecting a test result on the receiver 50. The absorber 120 includes an insulating layer 1200, a shielding layer 1202, and a number of absorbing projections 1204. The insulating layer 1200 is adhered to the sidewalls 110. The shielding layer 1202 is formed on the insulating layer 1200 opposite to the sidewalls 110. The absorbing projections 1204 are formed on the shielding layer 1202. In this embodiment, the insulating layer 1200 is made of wood. The shielding layer 1202 is made of ferrite. The absorbing projections 1204 is made of spongy material.

The antenna 30 is set on a lifting device 32. A height of the antenna 30 is adjusted by the lifting device 32. Thus, the antenna 30 receives the electromagnetic signals emitted from the test sample 3 at different heights. In this embodiment, the antenna 30 is a multiple antenna having a testing frequency band in a range from about 30 megahertz (MHz) to about 1 gigahertz (GHz). In other embodiments, the antenna 30 is a horn antenna having a testing frequency band in a range from about 1 GHz to about 18 GHz.

The testing table 20 rotates 360 degrees to show different faces of the test sample 3 to the antenna 30. In this embodiment, the testing table 20 is set at a predetermined height higher than the shielding board 104 to test the test sample 3 above the shielding board 104. In other embodiments, the testing table 20 is coplanar with the shielding layer 104 to test the test sample 3 on the shielding board 104. The testing table 20 is made of an insulating material.

The computer 60 is located outside the anechoic chamber 10 and is connected to the receiver 50 via an optical fiber 62. The computer 60 provides an operating interface of the receiver 50 to allow a user to operate the receiver 50 outside the anechoic chamber 10.

Because the amplifier 40 and the receiver 50 are located inside the anechoic chamber 10, a length of the coaxial cable 42 for transmitting signals is shortened. Thus, an attenuation of the transmitted signals is reduced, and an equipment cost is lowered. In addition, electromagnetic signals from outside the anechoic chamber 10 are prevented from affecting the amplifier 40 and the receiver 50.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments.

What is claimed is:

1. An electromagnetic compatibility testing system, comprising:
an anechoic chamber shielding electromagnetic signals;
a testing table located in the anechoic chamber and configured to hold a test sample;
an antenna set in the anechoic chamber and configured to receive an electromagnetic signal emitted from the test sample;
an amplifier connected to the antenna via a coaxial cable; and
a receiver connected to the amplifier via the coaxial cable;
wherein the electronmagnetic signal received by the antenna is amplified by the amplifier and is transmitted to the receiver for analyzing.

2. The electromagnetic compatibility testing system of claim 1, further comprising a computer located outside the anechoic chamber, wherein the computer is connected to the receiver via an optical fiber, and the computer provides an operating interface for the receiver.

3. The electromagnetic compatibility testing system of claim 1, wherein the anechoic chamber comprises a testing part, a shielding part, and a shielding board set between the testing part and the shielding part, and the shielding board comprises a grounded shielding sheet set on a surface of shielding board.

4. The electromagnetic compatibility testing system of claim 3, wherein the testing table and the antenna is set in the testing part, and the amplifier and the receiver are set in the shielding part.

5. The electromagnetic compatibility testing system of claim 3, wherein the testing part comprises sidewalls and an absorber set on the sidewalls.

6. The electromagnetic compatibility testing system of claim 5, wherein the absorber comprises an insulating layer, a shielding layer, and a plurality of absorbing projections, the insulating layer is adhered to the sidewalls, the shielding layer is set on the insulating layer, and the absorbing projections are set on the shielding layer.

7. The electromagnetic compatibility testing system of claim 6, wherein the insulating layer is made of wood, the shielding layer is made of ferrite, and the absorbing projections is made of spongy material.

8. The electromagnetic compatibility testing system of claim 1, further comprising a lifting device, wherein the antenna is set on a lifting device, and the height of the antenna is adjusted by the lifting device.

9. The electromagnetic compatibility testing system of claim 1, wherein the antenna is a multiple antenna having a testing frequency band in a range from about 30 MHz to about 1 GHz.

10. The electromagnetic compatibility testing system of claim 1, wherein the antenna is a horn antenna having a testing frequency band in a range from about 1 GHz to about 18 GHz.

11. The electromagnetic compatibility testing system of claim 1, wherein The testing table rotates 360 degrees to show different faces of the test sample to the antenna.
